(19) United States
(12) Patent Application Publication
(10) Pub. No.: US 2002/0027294 A1
(43) Pub. Date: Mar. 7, 2002

(54) Electrical component assembly and method of fabrication

(76) Inventors: Herbert J. Neuhaus, Colorado Springs, CO (US); Michael J. Kenney, Colorado Springs, CO (US); Michael E. Wernle, Hohenkirchen (DE)

Correspondence Address: DORSEY & WHITNEY, LLP, SUITE 4700, 370 SEVENTEENTH STREET, DENVER, CO, 80202-5647, US

(21) Appl. No.: 09/812,140

(22) Filed: Mar. 19, 2001

Related U.S. Application Data
(63) Continuation of application No. 09/684,238, filed on Oct. 5, 2000.
(60) Provisional application No. 60/220,027, filed on Jul. 21, 2000.
(60) Provisional application No. 60/233,561, filed on Sep. 19, 2000.

(51) Int. Cl. H01L 23/48; H01L 23/52

(52) U.S. Cl. 257/778; 257/738; 257/737; 257/787

(57) ABSTRACT

An electrical component assembly and method for the fabrication of the assembly in which particles are affixed to metal contact surfaces and pressure is applied to cause the particles to penetrate into at least one of the metal contact surfaces. In one method, hard particles are applied to one of the metal surfaces by electroplating the particles in a plating bath. In another method, the hard particles are applied to a non-conductive adhesive layer positioned between an electronic component and a substrate. Once pressure is applied to either the electronic component on the substrate, a permanent, electrically conductive bond is formed.

### CROSS REFERENCES TO RELATED APPLICATIONS

This application is related to and claims the benefit of priority of the following applications, which are hereby incorporated herein by reference: U.S. application Ser. No. 09/684,238 entitled “Electrical Component Assembly and Method of Fabrication,” filed Oct. 5, 2000, U.S. Provisional application Ser. No. 60/220,027 entitled “Advances in Materials for Low Cost Flip-Chip,” filed Jul. 21, 2000; and U.S. Provisional application Ser. No. 06/233,561 entitled “Manufacturing of Low Cost Smart Labels., filed Sep. 19, 2000.

### FIELD OF THE INVENTION

This invention relates, generally, to electrical component assemblies and methods for their fabrication and, more particularly, to structures and methods for electrical and mechanical connection of semiconductor flip-chips and flip-chip modules to a substrate.

### BACKGROUND OF THE INVENTION

Flip-chip technology is well known in the art. A semiconductor chip having solder bumps formed on the active side of the semiconductor chip is inverted and bonded to a substrate through the solder bumps by reflowing the solder. Structural solder joints are formed between the semiconductor chip and the substrate to form the mechanical and electrical connections between the chip and substrate. A narrow gap is left between the semiconductor chip and the substrate.

One obstacle to flip-chip technology when applied to polymer printed circuits is the unacceptably poor reliability of the solder joints due to the mismatch of the coefficients of thermal expansion between the chip, having a coefficient of thermal expansion of about 3 ppm/° C., and the polymer substrate, e.g. epoxy-glass having a coefficient of thermal expansion of about 16 to 26 ppm/° C., which causes stress build up in the solder joints. Because the structural solder joints are small, they are thus subject to failures.

In the past, the solder joint integrity of flip-chip interconnects to a substrate has been enhanced by underfilling the volume between the chip and the substrate with an underfill encapsulate material composed of a suitable polymer. The underfill material is typically dispensed around two adjacent sides of the semiconductor chip, then the underfill material slowly flows by capillary action to fill the gap between the chip and the substrate. The underfill material is then hard-baked for an extended period. For the underfill encapsulant to be effective, it is important that it adhere well to the chip and the substrate to improve the solder joint integrity. Underfilling the chip with a subsequently cured encapsulant has been shown to reduce solder joint cracking caused by thermal expansion mismatch between the chip and the substrate. The cured encapsulant reduces the stresses, induced by differential expansion and contraction, on the solder joints. The underfill process, however, makes the assembly of encapsulated flip-chip printed wire boards (PWB) a time consuming, labor intensive and expensive process with a number of drawbacks.

To join the integrated circuit to the substrate, a flux, generally a no-clean, low residue flux, is placed on the chip or substrate. Then the integrated circuit is placed on the substrate. The assembly is subjected to a solder reflowing thermal cycle, soldering the chip to the substrate. The surface tension of the solder aids to self align the chip to the substrate terminals. After reflow, due to the close proximity of the chip to the substrate, removing flux residues from under the chip is such a difficult operation that it is generally not done. Therefore the flux residues are generally left in the space between the chip and the substrate. These residues are known to reduce the reliability and integrity of the encapsulant.

After reflow, underfill encapsulation of the chip generally follows. In the prior art, the polymers of choice for the underfill encapsulation have been epoxies, the coefficient of thermal expansion and moduli of the epoxies being adjusted with the addition of inorganic fillers. To achieve optimum reliability, a coefficient of thermal expansion in the vicinity of 25 ppm/° C. is preferred and a modulus of 4 GPa or more. Since the preferred epoxies have coefficients of thermal expansion exceeding 80 ppm/° C. and moduli of less than 4 GPa, the inorganic fillers selected generally have much lower coefficients of thermal expansion and much higher moduli so that in the aggregate, the epoxy-inorganic mixture is within the desired range. Additionally, the underfilling process is a costly, time-consuming process during flip-chip assembly, because the material must flow through the tiny gap between the chip and the substrate.

In addition to the need for an underfilling process, the flip-chip bonding techniques of the prior art have at least three other principal disadvantages:

1. The application of underbump metallization and solder bumps to a wafer is a time-consuming, multi-step process that reduces product yield;

2. The reflowing of the solder bump and then underfilling and curing the encapsulant result in reduced production efficiency; and

3. The flux residues remaining in the gap between the chip and the substrate reduce the adhesive and cohesive strength of the underfill encapsulating adhesive, affecting the reliability of the assembly.

Other prior art methods of encapsulating the chip have attempted to overcome these limitations by applying gold studs to the contact sites on the chip and attaching the studded chip to a printed circuit using a conductive adhesive. This method suffers from the need to wire bond the studs one by one to the chip, a slow and inefficient process. Also, conductive adhesives are known to age with time and environmental exposure, causing unreliable interconnections. In addition, most implementations of this approach in actuality still require the underfill.

In another prior art method described in U.S. Pat. No. 5,128,746 to Pennisi, a method is disclosed in which an adhesive material including a fluxing agent is applied to the chip or substrate. The chip is positioned on the substrate and the solder bumps are reflowed. During the reflow step, the fluxing agent promotes wetting of the solder to the substrate metallization pattern and the adhesive material is cured, mechanically interconnecting and encapsulating the substrate to the component. The limitation of this technique is that in order for the molten solder to readily wet the substrate metallization and also to allow the solder, through surface tension, to self-align the chip bumps to the substrate metallization pattern, the material must maintain very low viscosity during the reflow step. But the viscosity of these materials is severely increased by the presence of the required inorganic fillers.

Another limitation of prior art flip-chip attachment methods relates to the difficulty of performing rework. Chip removal, once underfill has been performed, is very destructive to both the printed circuit board and the chip. Rework is extremely difficult, if not impossible, with prior art materials and processes. For example, the prior art procedure for removing an encapsulated die from a printed wire board is to grind it off manually.

Yet another limitation of the prior art is the expense of applying solder bumps to a chip. The solder bumps have been applied to chips by one of several methods. Coating the solder on the chip bumps by evaporation of solder metals through a mask is one such method. This method suffers from 1) long deposition times, 2) limitations on the compositions of solder that can be applied to those metals that can be readily evaporated, and 3) evaporating the metals over large areas where the solder is ultimately not wanted. Also, since most solders contain lead, a toxic metal, evaporation involves removal and disposal of excess coated lead from equipment and masks.

Electroplating of the solder onto the chip pads through a temporary sacrificial mask is another common prior art method. Electroplating is a slow and expensive process that also deposits the solder over large areas where the solder is ultimately not wanted. Another method is to screen print solder paste on the chip pads through a stencil, then reflowing the solder to form a ball or bump on the pad. This technique is limited to bump dimensions that can be readily stencil printed, so it is not practical in bump pitches of 50 microns or less.

Yet another method is to apply a thick layer of photoresist on the chip, expose the resist through a mask, and develop the resist to create openings through the resist to the chip pads beneath. Subsequently, the openings are filled with solder paste. The final step is removal of the thick photoresist and reflowing the solder to create a bump or ball on the chip pads. This method is preferable to the other methods described due to its lower cost. Yet the removal of the thick photoresist from the chips after solder reflow is a cumbersome procedure that often damages the chips and the solder bumps.

All the foregoing methods are generally performed prior to dicing the wafer on which the semiconductor chips are fabricated. Accordingly, the application of bumps can be carried out on many chips simultaneously.

The prior art also teaches methods in which metallic particles are used to make electrical interconnections. For example, U.S. Pat. No. 4,814,040 to Ozawa teaches a method for connecting electrical contact pads employing a liquid adhesive filled with nickel particles that can pierce the contact pad metallizations. However, this technique is difficult to use for the fabrication of selective interconnections required in the attachment of an electrical component with many contact pads, such as an integrated circuit, to a printed circuit.

Accordingly, improvement is needed in the bonding structures and fabrication techniques of electrical component assemblies, such as flip-chip assemblies, which includes the formation of a large number of bonds in a small surface area. In particular, improvement of the flip-chip bonding process is needed to decrease the number of steps and to provide a more efficient process.

### Brief Summary

The advantages of the present invention include, but are not limited to, the elimination of several manufacturing steps, which simplifies the process for component assembly and shortens the manufacturing cycle time. The invention also provides electrical assemblies having improved electrical performance, such as lower contact resistance than the prior art stud or stud and conductive paste approach. The invention eliminates the need for sockets and connectors, which allows for the fabrication of very small electrical assemblies. Further, the method of the invention is easy to implement using lower cost equipment than the prior art. The invention also provides improved reliability due to the use of tough inert bonding materials.

In one aspect of the invention, there is provided a general method for joining a first metal surface to a second metal surface and, more specifically, the bonding of surfaces to form electrical interconnect sites on electrical components. In one embodiment, the method includes applying a plurality of hard particles to at least a portion of one of the first metal surface. The hard particles are formed from a substance that is harder than one or both of the metal surfaces. Next a non-conductive adhesive is disposed between said metal surfaces, and the metal surfaces are brought together to form an interface. A compressive “force” is applied to the surfaces in a direction generally normal to the interface. This may be accomplished in some instances merely by alignment of the contacts and in others by applying a substantial additional force. Preferably, the force should be sufficient such that at least a portion of the hard particles penetrate through the adhesive and pierce the second metal surface. However, the purpose will be accomplished so long as the particles contact the respective surfaces sufficiently to form an electrical connection. The applied compressive force may be released. Nevertheless, the metal surfaces are thereafter held together by the adhesive and the effect of hard particles that remain pierced in the second metal surface.

Unlike the prior art, in the inventive method, the non-conductive adhesive itself is providing the principal force required to hold the joint together. The method of the invention can also make an electrical coupling between the first and second metal surfaces. Additionally, the method of the invention can form a thermal coupling between the first and second metal surfaces. Variations of the inventive method include applying the adhesive to the first or the second metal surfaces, or to both metal surfaces.

In another embodiment, a film adhesive is disposed between two surfaces at the time of assembly. The adhesive may be a permanently hardenable adhesive, which is hardened before the compressive force is removed, as for instance a hot melt adhesive, or a polymerizable adhesive. Alternatively, the adhesive may be pressure-sensitive adhesive. Accordingly, the method of the invention can form either a permanent adhesive bond, or a temporary adhesive bond.

Non-conductive adhesives suitable for use in the present invention include, for example, cyanoacrylate materials such as SuperGlue™ or Loctite TAK_PAK 444/ Cyanoacrylate is an inexpensive liquid that is easy to dispense. It is strong and cures very rapidly. Suitable hot melt adhesives include, for example, 3M 3792-LM-Q available from the 3M Company in St. Paul, Minn.

For chip attachment the adhesive must not contain impurities that would adversely affect the semiconductor chip. Sodium and chloride ions are known to cause silicon chips to fail. The industry recognizes a special purity grade, e.g., “electronics grade,” of adhesives with virtually no ionic contamination. In chip applications an electronics grade adhesive would be used because the adhesive comes into intimate contact with the semiconductor.

The hard particles may be affixed to the metal surface by plating a thin metal layer over them on the first metal surface. Such a method can be carried out by positioning a substrate under a mesh electrode located within a metal plating bath. Particles within the bath pass through the mesh electrode and settle on the substrate. A metal, such as nickel, is simultaneously deposited over the particles.

The hard particles can be formed from a metal, metal alloy, or an intermetallic. The metals include, for example, copper, aluminum, nickel, tin, bismuth, silver, gold, platinum, paladium lithium, beryllium, boron, sodium, magnesium, potassium, calcium, gallium, germanium, rubidium, strontium, indium, antimony, cesium, barium, and intermetallics and alloys of these metals. As described later herein, nickel is a preferred metal. The hard particles can also be formed from a non-metallic material, such as, metal oxides, nitrides, borides, silicon and other carbides, beryllium, boron fibers, carbon fibers, garnet or diamond. Diamond is a preferred non-metallic hard particle. Where non-metallic particles are used, the hard particles are surrounded by a conductive metal. Nickel is a preferred coating for such particles. Where a thermal conductor is desired diamond and ceramics are preferred materials.

As previously described, the method of the invention is particular useful where the metal surfaces function as an electrical interconnection pad of a printed circuit board or other electrical component. The method of the invention finds particular value in applications where the printed circuit board is a smart card chip module or smart label and where the electrical component is a semiconductor chip.

In yet another aspect of the invention, an electrical component assembly is provided that includes a substrate having a plurality of electrical contact sites on a surface of the substrate. A plurality of hard particles resides on the substrate, such that each of the electrical contact sites has at least one hard particle affixed to the electrical contact site. Such an assembly is particularly useful for the ease with which it can be attached to a printed circuit.

In still another aspect of the invention, a method is provided for attaching an electrical component to a printed circuit board having a plurality of electrical contact sites on a surface of the board. An electrical component is also provided having a plurality of electrical contact sites on a surface of the component. Each electrical contact site on the electrical component has a corresponding electrical contact site on the surface of the printed circuit board.

The electrical component further includes a plurality of hard particles positioned on the electrical component, such that each of the electrical contact sites located on the surface of the electrical component has at least one hard particle associated with it. The hard particles can comprise a substance that is harder than the electrical contact sites on the surface of the printed circuit board. The hard particles can be affixed to the electrical contact sites of the component. Then a non-conductive adhesive is place between the electrical component and thee printed circuit board such that at least selected portions of the surfaces of the printed circuit board and the electrical component and its hard particles are covered by adhesive.

Next, the electrical component is positioned relative to the printed circuit board such that at least one hard particle on each contact on the substrate is in contact with its corresponding electrical contact site on the printed circuit board. A compressive force is then applied to the component and printed circuit board so that the hard particles on the component penetrate the adhesive to contact and, preferably, pierce the electrical contact sites on the printed circuit board. The adhesive provides sufficient compressive force to keep the surfaces together so that the hard particles that pierced the surface of the printed circuit board remain in that position.

In another aspect of the invention, the electrical component described previously is one of a plurality of electronic components on a substrate. Each component has at least one electrical contact site on an active surface. In this embodiment, the hard particles are applied to the substrate, such that each of the electrical contact sites has at least one hard particle affixed to its associated contact site.

Finally, the substrate is divided to singularize the electrical component assemblies into many components, thus producing many components simultaneously in one step or one operation. The non-conductive adhesive may be applied to these components before or after they are singulated from their substrate. The adhesive may also be applied to cover substantially all of the substrate, or if desired, the adhesive may cover only selected portions of the substrate.

The method of the invention is particularly applicable to the fabrication of semiconductors where the substrate is a semiconductor wafer. Additionally, the substrate may be a flexible circuit tape. Further, the substrate may be a flexible tape of smart card chip modules or smart labels. Again, a non-conductive adhesive material can be applied to at least selected portions of the surface of these substrates and to the hard particles prior to subdividing the substrate. Alternately, the adhesive material can be applied to at least selected portions of the surface of the substrate and to the hard particles after subdividing the substrate.

In a still further embodiment of the invention, the hard particles are affixed to the printed circuit or electrical component to create a component assembly with the hard particles on it. The attachment may be accomplished by plating the particles as described previously. Alternately, the particles may be fixed by means of the adhesive itself. In another aspect, the hard particles remain unattached to either surface to be joined, and instead, the particles reside in the adhesive. In this embodiment, the entire adhesive surface may contain such particles. In another embodiment, the hard particles are applied to the adhesive in such a manner that they reside only in selected regions of the adhesive. Those selected regions may correspond with the electrical contact sites to be interconnected on the substrate or component.

A process for applying hard particles and additional metallization can be carried out in a multi-stage plating process. A substrate, such as a flexible circuit tape, is drawn through a metal plating bath to form a nickel base layer. Then, particles are plated on the nickel base in a nickel-particle plating bath. The circuit tape is then drawn through a second metal plating bath to form a metal layer overlying the particles to provide conductivity and to secure the particles pending assembly with the adhesive and mating contacts. Additional plating steps can be carried out to form one or more particle anchoring layers overlying the plated hard particles.

### BRIEF DESCRIPTION OF THE DRAWING

FIG. 1 illustrates, in cross-section, an electrical component assembly arranged in accordance with one embodiment of the present invention.

FIG. 2 illustrates, in cross-section, an electrical component and a substrate prior to assembly and arranged in accordance with a first process embodiment of the invention, in which hard particles are affixed to an electrical component and a non-conductive adhesive is applied to a printed circuit substrate.

FIG. 3 illustrates, in cross-section, an electrical component and a substrate prior to assembly and arranged in accordance with a second process embodiment of the invention, in which hard particles are affixed to a printed circuit and a non-conductive adhesive is applied to the electrical component.

FIG. 4 illustrates, in cross-section, an electrical component and a substrate prior to assembly and arranged in accordance with a third process embodiment of the invention, in which hard particles are affixed to a non-conductive adhesive disposed on a substrate.

FIG. 5 illustrates, in cross-section, an electrical component and a substrate prior to assembly and arranged in accordance with a fourth process embodiment of the invention, in which hard particles are affixed to a non-conductive adhesive disposed on the electrical component.

FIGS. 6A and 6B illustrate, in cross-section, a substrate and an electrical component undergoing an attachment method in accordance with a fifth process embodiment of the invention, in which a non-conductive adhesive contains hard particles, and in which only selected portions of the adhesive contain hard particles positioned in spaced relationship to the contact sites on the substrate and the electrical component.

FIGS. 7A and 7B illustrate, in cross-section, a substrate and an electrical component undergoing an attachment method in accordance with a sixth process embodiment of the invention, in which an (otherwise) non-conductive adhesive contains a substantially uniform layer of hard particles.

FIG. 8 is a partial cross sectional view of a dual-interface smart card assembly having contact metallization in accordance with the invention.

FIG. 9 is a schematic diagram of an exemplary plating process for plating hard particles to contact lands on a flexible circuit substrate.

FIG. 10 is a schematic drawing of an exemplary particle plating bath arranged in accordance with the invention.

### DETAILED DESCRIPTION OF THE PREFERRED EMBODIMENTS

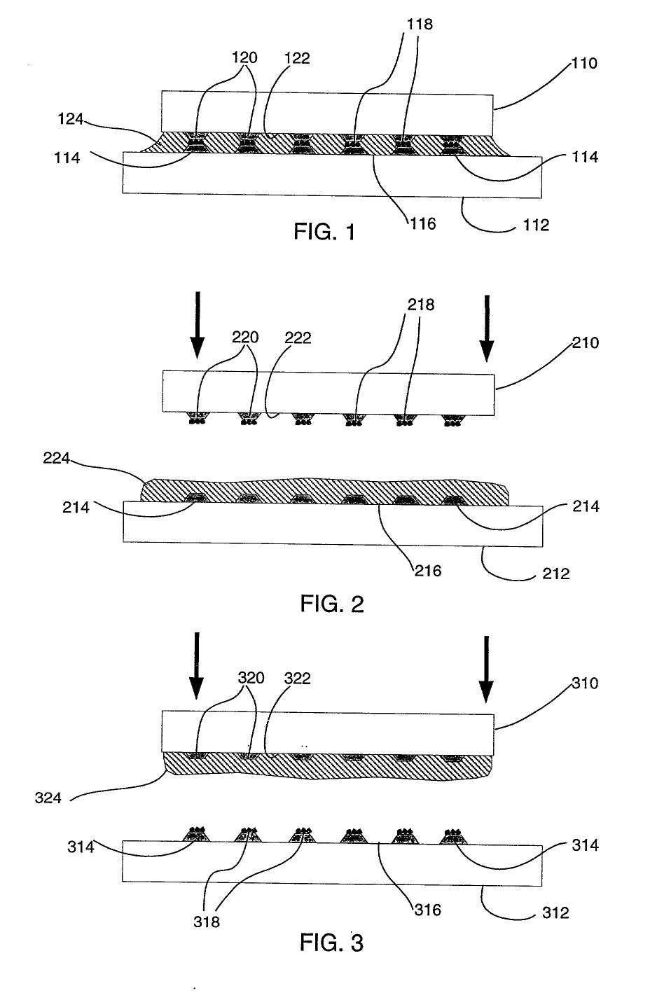

Shown in FIG. 1 is a cross-sectional view of an electrical component assembly arranged in accordance with one embodiment of the invention. An electrical component 110 is mounted on a substrate 112. Electrical component 110 can be one of a number of different electrical components including a semiconductor integrated circuit device such as a memory device, a logic device, a microprocessor, and the like, or a passive component such as a capacitor, resistor, switch, connector, etc. Further, electrical component 110 can be a flex circuit or a chip module having one or more semiconductor devices mounted thereon. Substrate 112 can be one of a number of electrical component mounting substrates including a flexible chip carrier, a printed circuit board, a flexible leadframe tape, a smart card module base, a smart label module base, and the like.

A plurality of electrical contact sites, referred to herein as “contact lands” 114, reside on a bonding surface 116 of substrate 112 and are arranged to receive corresponding hard particles 118, which in the present embodiment, are affixed to metallized bonding pads 120 of electrical component 110. Hard particles 118 can be formed from a metal, metal alloy or an intermetallic. In accordance with the invention hard particles 118 can be formed from, for example, copper, aluminum, nickel, tin, bismuth, silver, gold, platinum, paladium lithium, beryllium, boron, sodium, magnesium, potassium, calcium, gallium, germanium, rubidium, strontium, indium, antimony, cesium, barium, and intermetallics and alloys and intermetallics of these metals. Hard particles 118 can also be formed from a non-metallic material, such as, metal oxides, nitrides, borides, silicon and other carbides, beryllium, boron fibers, carbon fibers, garnet or diamond, garnet or diamond. In a preferred embodiment of the invention, hard particles 118 are composed of a diamond core plated with a layer of nickel.

Each of the contact lands 114 is metallized and electrically conductive to provide an electrical interconnection between electrical component 110 and substrate 112. Metallized bonding pads 120 can be arrayed on the surface of a semiconductor device and arranged for the flip-chip attachment of the semiconductor device to substrate 112. Alternatively, metallized bonding pads 120 can be located on a bonding surface of a chip carrier or a flex circuit populated with one or more semiconductor devices. In a preferred embodiment of the invention, metallized bonding pads 120 and contact lands 114 are metallized with a layer of nickel.

In the electrical component mounting arrangement illustrated in FIG. 1, a gap 121 is formed between bonding surface 116 of substrate 112 and a face surface 122 of electrical component 110. Gap 121 typically varies from about 0.5 to about 5 mils. Gap 121 is completely filled with an adhesive material 124. In one embodiment of the invention, non-conductive adhesive material 124 is a hardenable composition. In another embodiment of the invention, adhesive material 124 is a contact adhesive composition.

In the present invention, a preferred adhesive material is one that sets very rapidly without need for heat or other treatments, such as cyanoacrylate and the like. Alternatively, adhesive material 124 can be an ultraviolet-light (UV) curable polymer composition. Additionally, other types of adhesives can be used, such as a permanently hardenable adhesive. For example, adhesive material 124 can be a hot melt adhesive, a polymerizable adhesive, and the like. In yet another alternative, adhesive material 124 can be a pressure-sensitive adhesive. Non-conductive adhesives suitable for use in the present invention include, for example, cyanoacrylate materials such as SuperGlue™ or Loctite TAKPAK 444/ Cyanoacrylate is an inexpensive liquid that is easy to dispense. It is strong and cures very rapidly. Suitable hot melt adhesives include, for example, 3M 3792-LM-Q available from the 3M Company in St. Paul, Minn. Suitable pressure sensitive adhesives include Scotch Brand 467 Hi Performance Adhesive and Scotch brand F9465PC adhesive transfer tape. Preferably, the adhesive material employed should have reduced levels of certain impurities that can adversely affect the component or the interconnection. In particular, sodium and chlorine ions are know to cause semiconductor chips to fail and promote corrosion of electrical interconnections under humid conditions. FIG. 2 illustrates a cross-sectional view of electrical component 210 and substrate 212 prior to assembly and arranged in accordance with a first process embodiment of the invention. Substrate 212, having separate discrete contact lands 214 thereon, is pre-coated with non-conductive adhesive material 224 prior to mounting electrical component 210 to substrate 212. Adhesive material 224 is applied to the substrate 212 in as either a liquid or an adhesive tape. Hard particles 218 are affixed to the corresponding metallized bonding pads 220 on face surface 222 of component 210. Adhesive material 224 is uniformly spread across bonding surface 216 of substrate 212 and over contact lands 214 and covering the remainder of the substrate 212. Electrical component 210 is then positioned so that metallized bonding pads 220 with affixed hard particles 218 are facing substrate 212 and aligned with contact lands 214 of substrate 212.

To mount electrical component 210 to substrate 212, metallized bonding pads 220 with affixed hard particles 218 are moved into alignment with contact lands 214, and a compressive force is applied, as indicated by the arrows shown in FIG. 2. Under the compressive force, hard particles 218 pierce into contact lands 214 of substrate 212. Depending upon the particular non-conductive adhesive material used in the assembly, adhesive material 224 may be hardened by either a self-hardening mechanism or by thermal or UV curing of the adhesive, and then the compressive force is released producing the assembly illustrated in FIG. 1. Importantly, hardened adhesive 224 provides a continuous seal between electrical component 210 and substrate 212 and maintains the compressive force between substrate 212 and electrical component 210, such that hard particles 218 remain partially embedded in contact lands 214 after the initially applied compressive force is released.

FIG. 3 illustrates a cross-sectional view of electrical component 310 and substrate 312 prior to assembly and arranged in accordance with a second process embodiment of the invention. Electrical component 310, having separate discrete metallized bonding pads 320 thereon, is pre-coated with adhesive material 324 prior to assembly with substrate 312. Similar to the previous process embodiment, non-conductive adhesive material 324 is applied to electrical component 310 as either a liquid or an adhesive tape.

In the present embodiment, hard particles 318 are affixed to the corresponding contact lands 314 on bonding surface 316 of substrate 312. Adhesive material 324 is uniformly spread across face surface 322 of electrical component 310 over metallized bonding pads 320 and covering the remainder of face surface 322. Electrical component 310 is then positioned so that metallized bonding pads 320 are facing substrate 312 and aligned with contact lands 314 having affixed hard particles 318.

Next, metallized bonding pads 320 are moved into alignment with contact lands 314 and a compressive force is applied, as indicated by the arrows shown in FIG. 3. Under the compressive force, hard particles 318 pierce into the metallized bonding pads 320 of component 310. Adhesive material 324 is hardened as previously described, and then the compressive force is released producing the assembly illustrated in FIG. 1. As in the previous embodiment, hardened adhesive 324 provides a continuous seal between the component 310 and the substrate 312. Hardened adhesive material 324 maintains the compressive force between substrate 312 and electrical component 310, such that hard particles 318 remain partially embedded in metallized bonding pads 320 after the initially applied compressive force is released.

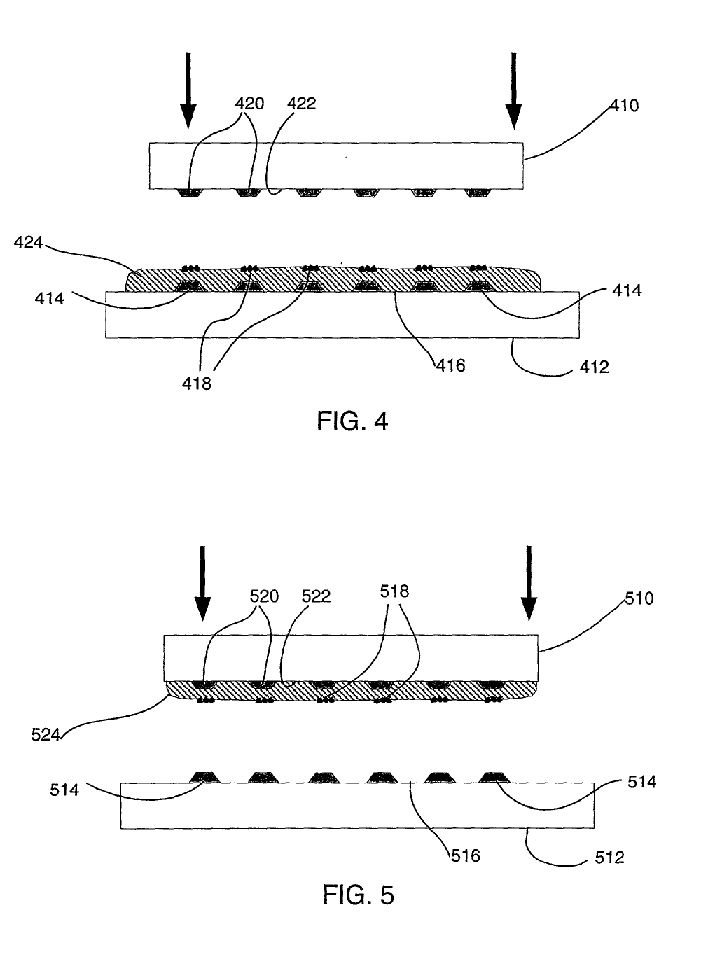

FIG. 4 illustrates a cross-sectional view of electrical component 410 and substrate 412 prior to assembly and arranged in accordance with a third process embodiment of the invention. Substrate 412, having separate discrete contact lands 414 thereon, is pre-coated with non-conductive adhesive material 424 prior to assembly with component 410. As in the first process embodiment described above, adhesive material 424 is applied to substrate 412 as either solid or adhesive tape. Adhesive material 424 is uniformly spread across bonding surface 416 of substrate 412 and over contact lands 414.

In the present embodiment, hard particles 418 are affixed to a surface 426 of adhesive material 424 and are directly and selectively positioned in spaced relationship to corresponding contact lands 414 on top surface 426 of substrate 412. Hard particles 418 can be selectively positioned on surface 426 by, for example, selectively spraying a particle slurry, or by applying a stencil to surface 426 and applying a particle slurry to the stencil, or the like. Once hard particles 418 are applied to surface 426, electrical component 410 is positioned so that metallized bonding pads 420 are facing substrate 412 and aligned with contact lands 414. Hard particles 418 reside on the surface of adhesive material 424 directly between contact lands 414 and metallized bonding pads 420.

To mount electrical component 410 to substrate 412, metallized bonding pads 420 are moved into alignment with hard particles 418 and contact lands 414, and compressive force is applied, as previously described. Under the compressive force, hard particles 418 pierce into adhesive material 424 and contact lands 414 of substrate 412, and simultaneously pierce metallized bonding pads 420 of component 410. The adhesive 424 may be hardened as previously described and then the compressive force is released, producing the assembly illustrated in FIG. 1.

FIG. 5 illustrates a cross-sectional view of electrical component 510 and substrate 512 prior to assembly and arranged in accordance with a fourth process embodiment of the invention. Electrical component 510, having separate discrete metallized bonding pads 520 thereon, is pre-coated with non-conductive adhesive material 524 prior to assembly with substrate 512. As in the second process embodiment described above, adhesive material 524 is applied to electrical component 510 as either a solid or an adhesive tape. Adhesive material 524 is uniformly spread across face surface 522 of electrical component 510 and over metallized bonding pads 520 and covering the remainder of the electrical component 10.

In the present embodiment, hard particles 518 are affixed to surface 526 of adhesive material 524 directly and selectively in space relationship to corresponding metallized bonding pads 520 on face surface 522 of component 510. Electrical component 510 is then positioned so that metallized bonding pads 520 are facing substrate 512 and aligned to contact lands 514. Metallized bonding pads 520 with overlying adhesive material 524 and hard particles 518 are moved into alignment with contact lands 514, and compressive force is applied, as indicated by the arrows shown in FIG. 5. Under the compressive force, hard particles 518 pierce into adhesive material 524 and metallized bonding pads 520 of component 510, and simultaneously pierce contact lands 514 of substrate 512. Adhesive material 524 may be hardened as previously described and the compressive force is released, producing the assembly illustrated in FIG. 1.

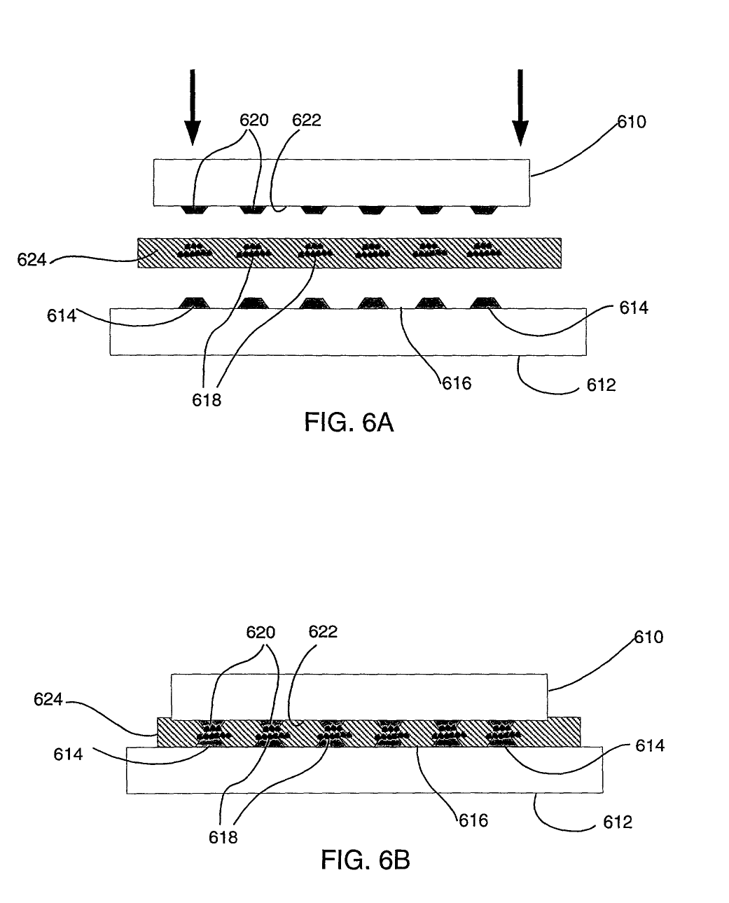

FIGS. 6A and 6B illustrate cross-sectional views of substrate 612 and electrical component 610 undergoing an attachment method in accordance with a fifth process embodiment of the invention. In the present embodiment, non-conductive adhesive material 624 exists on its own as stand-alone film prior to mounting electrical component 10 to substrate 612. Preferably, adhesive material 624 is either a solid material or an adhesive tape.

Hard particles 618 are preferably affixed within adhesive material 624 directly and selectively, such that when adhesive material 624 is positioned between electrical component 610 and substrate 612, hard particles 618 are in positioned in spaced relationship with corresponding metallized bonding pads 620. Hard particles 618 can be positioned within adhesive material 624 by, for example, forming a first layer of adhesive, then, affixing the hard particles 618 using spraying or a stencil as described above. After affixing hard particles 618, a second layer of non-conductive adhesive is formed to overlie the particles and first layer of adhesive. Multiple layers of hard particles 618 are shown suspended in adhesive material 624 in FIGS. 6A and 6B. However, single layers of hard particles 618 affixed within the adhesive material 624 and positioned corresponding to each metallized bonding pad 620 are sufficient.

Electrical component 610, substrate 612 and adhesive material 624 are then positioned so that metallized bonding pads 620 are facing substrate 612 and hard particles 618, suspended in adhesive material 624, are also aligned with contact lands 614 of substrate 612. Adhesive material 624 with suspended hard particles 618 is positioned between electrical component 610 and substrate 612. Then, metallized bonding pads 620 are moved into alignment with adhesive material 624 and contact lands 614, and compressive force is applied, as previously described. Under the compressive force, hard particles 618 simultaneously pierce through adhesive material 624 into metallized bonding pads 620 of electrical component 610 and into contact lands 614 of substrate 612. Adhesive material 624 is hardened as previously described, and then the compressive force is released, producing the assembly illustrated in FIG. 6B.

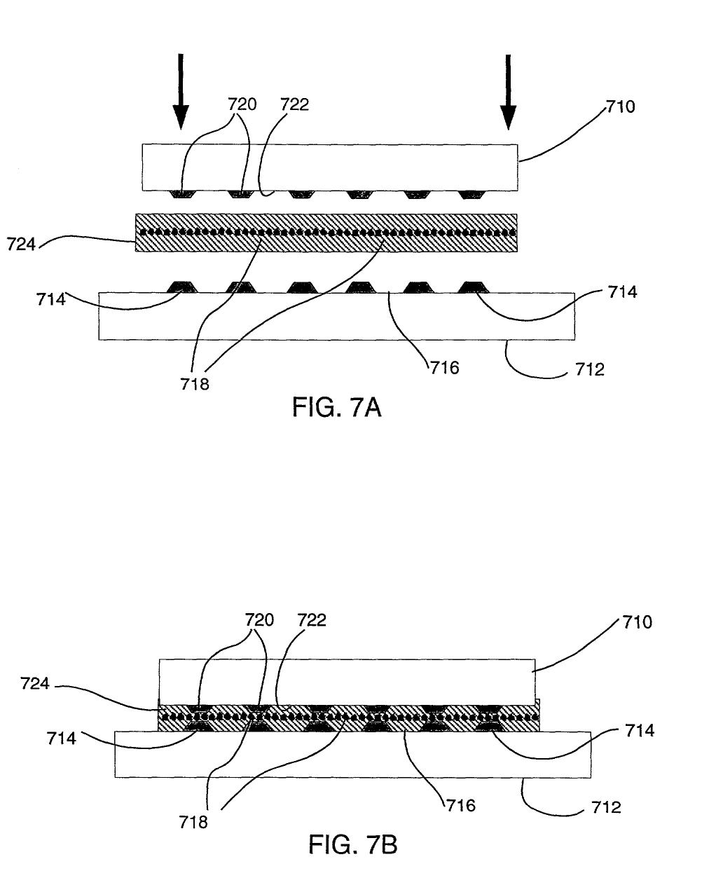

FIGS. 7A and 7B illustrate cross-sectional views of substrate 712 and electrical component 710 undergoing an attachment method in accordance with a sixth process embodiment of the invention. Similar with the fifth process embodiment, non-conductive adhesive material 724 exists on its own as stand-alone film prior to assembly. Preferably, adhesive material 724 is either a solid material or an adhesive tape. Hard particles 718 are suspended within adhesive material 724 and are randomly distributed throughout adhesive material 724 at a fill density that is less than the percolation limit of hard particles 718 in the adhesive 724. A substantially uniform layer of hard particles 718 can be formed within the adhesive material 724, by for example, first forming a first adhesive layer. A layer of hard particles 718 is then spread upon the first layer by, for example, spraying particle slurry onto the first adhesive layer. A second adhesive layer is then formed to overlie the hard particles 718 and the first adhesive layer. By maintaining hard particles 718 at a fill density below the percolation limit, the hard particles do not touch one another, even after compression.

Adhesive material 724 is positioned between the face surface 722 of electrical component 710 and bonding surface 716 of substrate 712. Electrical component 710 and adhesive material 724 are then positioned so that metallized bonding pads 720 are facing substrate 712 and are aligned with contact lands 714. As in the previous embodiment, an adhesive material 724 with suspended hard particles 718 is positioned between electrical component 710 and substrate 712. Then, metallized bonding pads 720 are moved into alignment with adhesive material 724 and contact lands 714, and a compressive force is applied, as previously described. Under the compressive force, hard particles 718 simultaneously pierce through the adhesive 724 and into metallized bonding pads 720 of electrical component 710 and contact lands 714. Adhesive material 724 is hardened as previously described and then the compressive force is released, producing the assembly illustrated in FIG. 7B. Importantly, since the hard particles do not touch one another, they do not conduct electricity laterally from one contact to a neighboring contact.

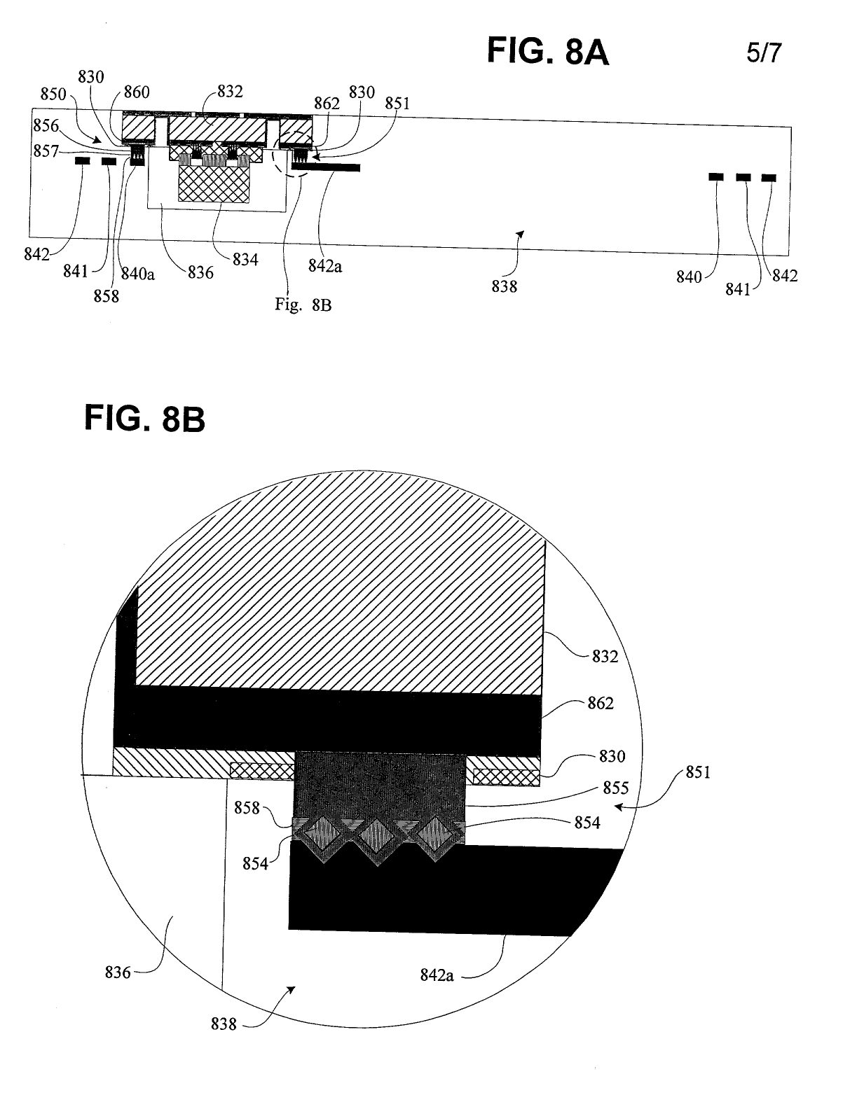

FIG. 8A illustrates a partial cross-sectional, side view of a dual-interface smart card assembly including contact in accordance with the invention. FIG. 8B illustrates a detailed enlargement of the contact assembly. In this case, the technology of the present invention is utilized to form a connection between the semiconductor chip module and the antenna. It could also be used to form the connection between the semi conductor chip and the module, i.e., the contact plate in a dual-interface smart card. A copper flex circuit 830 is mounted to a flexible substrate 832. Semiconductor (i.e., chip) device 834, flexible circuit 830 and flexible substrate 832 are mounted within a module cavity 836 located in a smart card body 838. Flexible circuit 830 is electrically connected to an antenna coil located adjacent to module cavity 836 in smart card body 838. The antenna illustrated consists of three loops or windings 840, 841 and 842. Other numbers of loops maybe used, typically 1, 2, 4 or even hundreds. Flexible circuit 830 is electrically connected to antenna contact 840a by a contact assembly 850 and to the other end of the antenna contact 842a by contact assembly 851.

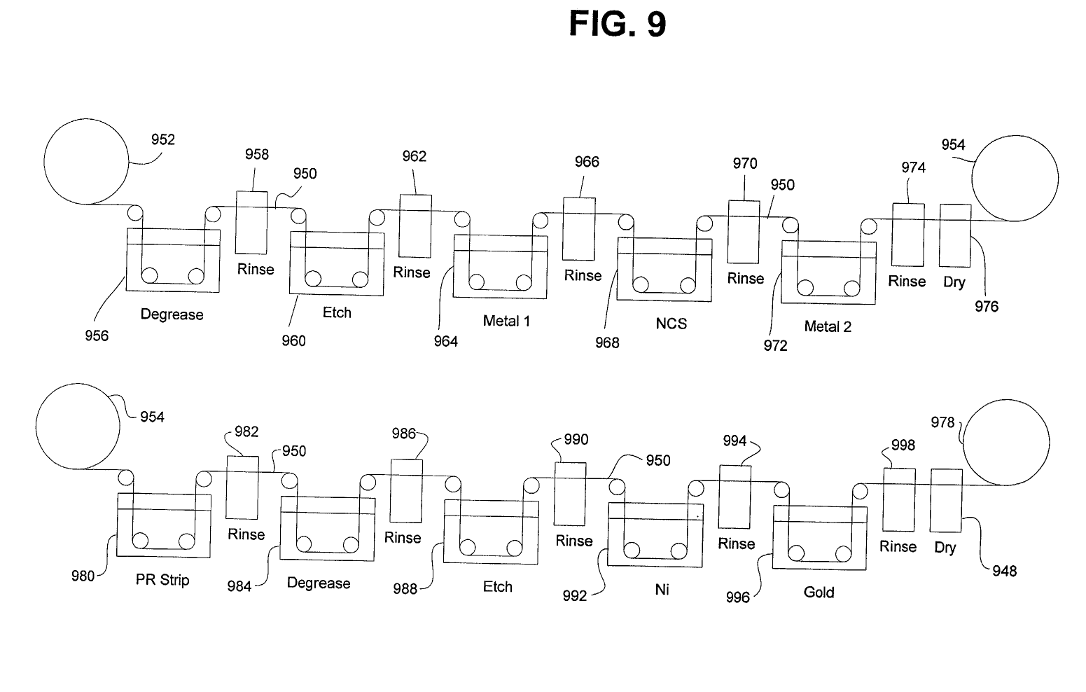

The antenna coils 840, 841 and 842 shown in the drawing reside in smart card body 838 at a specified depth below the shelf on which the circuit 830 rests. In some smart cards the antenna may be at the same level as the shelf . In the illustrated situation, however, antenna coil is located about 100 microns below the circuit 830 in a typical smart card design. To accommodate the submersion distance of the antenna coil, a thick layer of nickel 855 and 856 is plated on the contact lands 860 and 862 of flexible circuit 830 prior to plating hard particles and nickel onto the contact lands. In particular, contact assembly 850 includes a nickel layer 856 having a thickness of about 25 microns to about 100 microns and an overlying metallized hard particle layer 857 having a thickness of about 2 microns to about 50 microns. Similarly, contact assembly 851 has a layer of nickel 855, covered by a metallized hard particle layer 854. The contact assemblies 850 and 851 are covered with a non-conductive adhesive 858 before assembly of the flexible circuit 830 with the antenna. Alternatively, the antenna contacts 840a and 842a can first be covered by the adhesive 858 before the parts are aligned and pressed together. Those skilled in the art will appreciate that various modifications of contact assemblies 850 and 851 can be made depending upon the particular geometric features of the smart card assembly to which the metallization is to be used. For example, the plating thickness of contact assemblies 850 and 851 can vary substantially depending upon the particular smart card design. Further, semiconductor device 834 can be a flip-chip device bonded to flexible circuit 830 using any of the foregoing embodiments illustrated in FIGS. 1-7. An exemplary plating process for plating layers of nickel and diamond particles on the contact lands of a copper flex circuit tape in accordance with one embodiment of the invention will now be described. Illustrated in FIG. 9 is a schematic layout of an exemplary multi-stage process for metallizing contact lands on a flexible circuit tape. The process illustrated in FIG. 9 can be used, for example, to plate hard particles and contact lands on substrate, and to form metallized contact, such as the metallized contact 842 of the smart card in FIG. 8.

In a first stage of the process, a copper-clad flex circuit tape 950 is dispensed by a dispense reel 952 and is drawn through a series of process stages by a take-up reel 954. Prior to spooling circuit tape 950 onto dispense reel 952, photolithographic processing is carried out to form a patterned layer of photoresist (not shown) overlying circuit tape 950. The photoresist layer has contact openings therein that expose contact lands similar to those described above on circuit tape 950. During processing, circuit tape 950 is first conveyed from dispense reel 952 to a cleaning tank 956. Cleaning tank 956 contains an acidic cleaning solution and a wetting agent. For example, a mixture of formic and sulphuric acid can be used to remove organic films overlying the surface of the contact lands on circuit tape 950 that are exposed by the photoresist layer. Upon exiting cleaning tank 956, circuit tape 950 passes through a first rinse stage 958. First rinse stage 958 exposes circuit tape 950 to an aqueous rinsing solution to flush away residual cleaning solution and particulate matter. The first rinse stage 958, as well as the following indicated rinse stages, may also incorporate a pressure wash system over either the top of bottom of the tape, or both.

After cleaning, circuit tape 950 is conveyed to an etch tank 960. Etch tank 960 contains a copper etching solution that removes copper and copper oxides and other dielectric films overlying the surface of the contact lands. Preferably, etch tank 960 is charged with a potassium persulphate solution. After etching, circuit tape 950 passes through a second rinse stage 962 where residual etching solution and particulate matter are removed by exposure to an aqueous solution.

Following the dielectric etching step, circuit tape 950 enters a first metal plating bath 964. In first metal plating bath 964, the contact land on circuit tape 950 is preferably plated with a layer of nickel to a thickness of about 25 to about 100 microns. The specific thickness of the plated nickel layer will vary depending upon the particular type of electronic component assembly to be fabricated using circuit tape 950. Preferably, first metal plating bath 964 contains a low-stress nickel plating solution including nickel sulphamate and nickel bromide in a boric acid solution. After plating a nickel in first metal plating bath 964, circuit tape 950 passes through a third rinse stage 966, where an aqueous rinse solution removes residual chemicals and particulate matter from first metal plating bath 964.

Next, circuit tape 950 is fed into a particle plating bath 968. In particle plating bath 968, a layer of nickel-plated diamond particles are plated onto the plated nickel base layer. As will subsequently be described in greater detail, in particle plating bath 968, the nickel-plated diamond particles pass through a mesh anode located in the bath prior to contacting the metallized contact lands on circuit tape 950. Preferably, the mesh anode is constructed of platinum-coated titanium metal. After plating the particle layer, circuit tape 950 passes through a fourth rinse stage 970 to remove residual chemicals and particulate matter from particle plating bath 968.

After plating the particle layer, circuit tape 950 is fed into a second metal plating bath 972. In second metal plating bath 972, a second layer of nickel is plated over the particle layer to form a particle anchor layer that seals the particles to the contact metallization. Preferably, the particle anchor layer is plated to a thickness substantially one half the size of the particular hard particles. For example, for particles having a size of about 20 microns, the particle anchor layer is plated to a thickness of about 10 microns. After plating the nickel overcoat layer, circuit tape 950 passes through a sixth rinse stage 974 to remove residual chemicals and particulate matter from second metal plating bath 972. Finally, circuit tape 950 is dried by a drying system 976 to remove water and residual solvents from circuit tape 950 prior to the collection of circuit tape 950 by take-up reel 954.

Once the contact lands on circuit tape 950 have been metallized and affixed with hard particles, a second stage of the process may be undertaken to remove the photoresist and form a nickel and gold overcoat layer on circuit tape 950. Although the entire process is described herein in two stages, these stages can be combined into one process line, obviating the need for drying system 976 and take-up reel 954. In a single process line, the circuit tape would continue directly from the sixth rinse stage 974 to photoresist stripping tank 980. The two stage embodiment described herein, is shown merely to indicate that the process can be broken into multiple stages, for instance, to accommodate space limitations, or to provide greater flexibility depending upon the process result desired. Also, it may be desired to simply affix hard particles to contact lands in a metallization process, without further desire to strip photoresist or provide additional metallization at the same time.

The second stage of the process in the depicted embodiment continues by dispensing circuit tape 950 from take-up reel 954 through a series of process stages and finally drawing up circuit tape 950 by a take-up reel 978. Circuit tape 950 is dispensed by take-up reel 954 first into a resist stripping tank 980 that contains a photoresist dissolving solution, such as an alkaline solution of monoethylamine and butylcellusolve. Once the photoresist is removed, circuit tape 950 passes through a sixth rinse stage 982 and is conveyed into a cleaning tank 984. Cleaning tank 984 contains a solution similar to that contained in cleaning tank 956 for the removal of organic residues from circuit tape 950.

After rinsing chemical residues away in an seventh rinse stage 986, circuit tape passes into an etching tank 988. Etching tank 988 contains the previously described copper etching solution. Upon the removal of native oxides in etching tank 988, circuit tape 950 passes through an eighth rinse stage 990 prior to conveyance into a nickel plating bath 992. Preferably, nickel plating bath 992 contains a nickel plating solution similar to that described above with respect to nickel plating baths 964 and 972. In nickel plating bath 992, a layer of nickel having a thickness sufficient to act as a diffusion barrier for the underlying metallization is formed. Preferably, a nickel layer having a thickness of about 2 microns to about 25 microns and, more preferably, about 5 to about 15 microns, is plated onto circuit tape 950.

After rinsing away residual chemicals and particulates from nickel plating bath 992 in an ninth rinse stage 994, circuit tape 950 is conveyed to a gold plating bath 996. Gold plating bath 996 contains a gold plating solution, such as Technic Orosene 80, comprising potassium orocyanide. In gold plating bath 96, a gold layer is deposited on circuit tape preferably having a thickness of about 10 to about 40 micro-inches, and more preferably about 30 micro-inches.

After rinsing away chemicals and particulate matter from gold plating bath 96 in a tenth rinse stage 998, circuit tape 950 is dried in air dryer 948 prior to collection by take-up reel 978. Preferably, air drying systems 948 and 976 operate in order to remove water and residual solvents from circuit tape 950 prior to collection and storage on take-up reels 954 and 978.

Although the foregoing description is set forth with respect to nickel plating on a copper-clad flexible circuit, those skilled in the art will appreciate that other metallized contact structures can be formed using the process described above. For example, a variety of metals, intermetallics, and alloys, such as copper and tin-lead solder, and the like, can be plated onto both rigid substrates and the flexible circuit tape. Additionally, both rigid and flexible substrates can be materials such as epoxy substrate, epoxy-glass substrate, polyimide, Teflon, and bismalyimide triazine (BT) and the like. The flexible substrate need not be a flex circuit. The process can also be used to metallize and affix hard particles to small, rigid components such as ceramic circuit boards, modules, interposers, and other small circuit boards. Typically, metallization and hard particle deposition on such rigid components are performed in batch processes. However, these small, rigid components may be temporarily affixed or adhered to a flexible tape, preferably with a metallic adhesive. Using the flexible tape as a carrier, the small, rigid components can be drawn through the metallization and hard particle deposition process disclosed herein. A metallic adhesive is preferred in order to electrically connect the small, rigid component to a cathode circuit for plating to occur. Furthermore, the hard particles can be any of the materials described elsewhere in this specification. Those skilled in the art will also appreciate that the chemical composition of the various plating, etching, and rinsing solutions will change depending upon the particular metals used to form the metallized contacts.

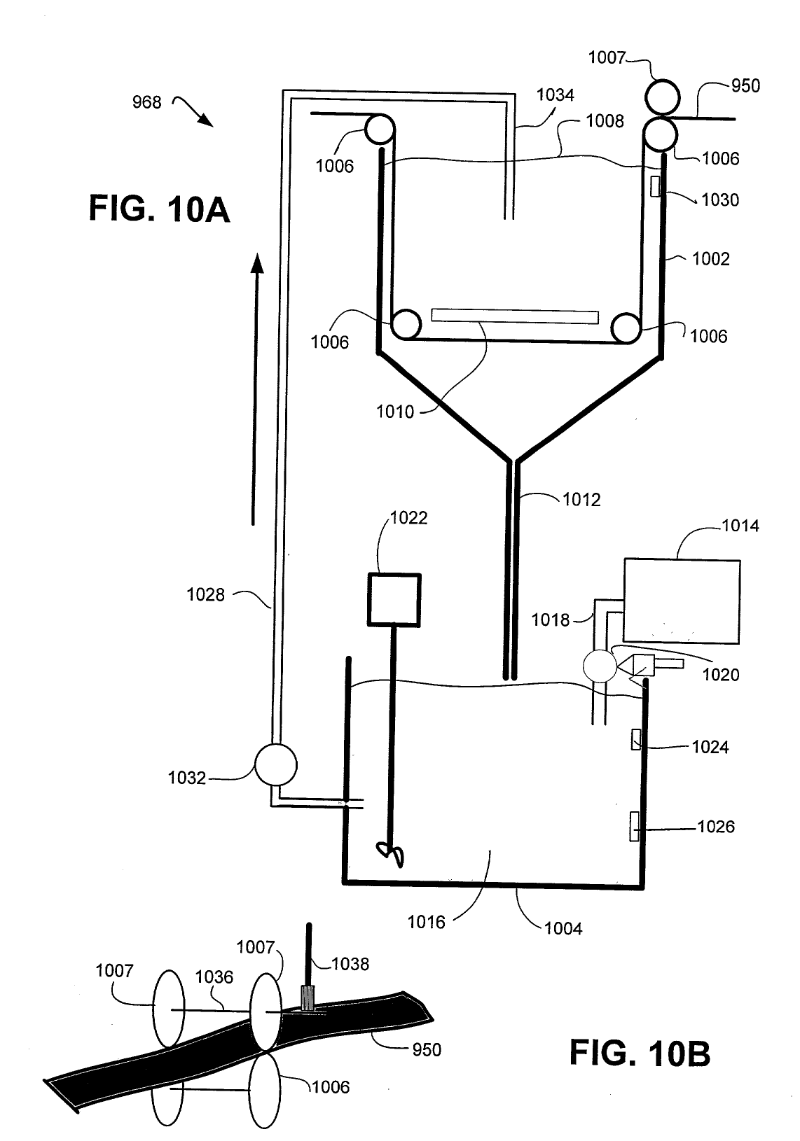

Shown in FIG. 10A is a schematic diagram of particle plating bath 968 arranged in accordance with one embodiment of the invention. Particle plating bath 968 includes a plating tank 1002 and a solution reservoir 1004. Plating tank 1002 contains a plating solution 1008 through which circuit tape 950 is drawn while being guided by pulleys 1006. Before its submersion in plating tank 1002, circuit tape 950 is negatively charged to a voltage of about 1 to about 2 volts such that the circuit tape 950 acts as a cathode to promote the metallic plating process. In a preferred embodiment, each edge of the circuit tape 950 is electrically conductive and in electrical connection with the portions of the surface of the circuit tape 950 to be plated.

Pulleys 1006 preferably consist of paired guide wheels or tracks on each side of the circuit tape 950 that support each edge of the circuit tape 950. As shown in Fig. 10B, pinch rollers 1007 press against the edges of the circuit tape 950 opposite the first set of guide wheels. Pinch rollers 1007 are electrically conductive and are in electrical connection with the conductive edges of the circuit tape 950, thereby providing the voltage to the circuit tape 950. Preferably, axel 1036 supporting pinch rollers 1007 is electrically conductive and connects pinch rollers 1007 to a voltage source via metal brush connection 1038. Each pair of paired guide wheels and pinch rollers 1007 are preferably mounted on respective common axels by frictional engagement, thereby allowing each guide wheel pair to be spaced closer together or farther apart from each other to accommodate varying widths of circuit tape 950.

A mesh anode 1010 of platinum coated titanium metal is positioned in a portion of plating tank 1002 above the circuit tape 950 and is positively charged to a voltage of about 1 to about 2 volts. The major plane of the anode 1010 is preferably placed in parallel with the major plane of the circuit tape 950 to foster uniform metallized plating. When plating hard particles, the circuit tape 950 is preferably horizontal in order to maximize the deposition of hard particles, which fall through the plating solution by gravity flow. In general, the hard particle flow is ideally perpendicular to the surface of the circuit tape 950 (or any other substrate desired to be plated). In practice, the circuit tape 950 can be up to a 45-degree angle to the hard particle flow and still achieve adequate particle deposition. A mesh anode 1010 having open spaces of approximately one-quarter inch mesh is preferred, allowing the hard particles to flow through the anode and deposit on the circuit tape 950. While still possible, a solid anode makes hard particle deposition on the circuit tape 950 more difficult.

During nickel-particle plating, diamond particles pass through openings (not shown) in mesh anode 1010 and deposit onto circuit tape 950. As previously described, plating solution 1008 is preferably a mixture of nickel sulphamate and nickel bromide in an aqueous boric acid solution. Preferably, plating solution 1008 has a nickel sulphamate concentration of about 300 to about 500 grams/liter, and a nickel bromide concentration of about 10 to about 20 grams/liter. Amounts of boric acid are added to obtain a pH of about 3 to about 4.5. Plating solution 1008 also includes wetting agents, and is preferably maintained at a temperature of about 50° C. to about 60° C.

The thickness of a nickel-particle layer formed on circuit tape 950 will depend upon several process parameters. For example, the deposition rate will vary with the current density for a given bath composition. Additionally, the transport speed of the tape and the residence time within the bath will also affect the metal thickness. Transport speeds of the circuit tape 950 are preferably between 0.13 mm/sec and 1.13 mm/sec. This range is based upon a current density in the particle plating bath 968 of between 100A/ft² and 200 A/ft². A preferred transport speed that provides the desired nickel layer thickness of between 25 and 100 microns before the hard particle deposition is about 0.3 mm/sec at a current density of about 100 A/ft². In accordance with the invention and in a preferred embodiment, the particle density in the particle plating bath 968 is adjusted as the other process parameters are adjusted, such that preferably a 10 to 100 percent monolayer, and more preferably about a 50 percent monolayer, of particles is plated onto circuit tape 950.

The concentration of particles in plating solution 1008 is maintained by recirculation from solution reservoir 1004. Solution reservoir 1004 receives return solution from plating bath 1002 through recirculation tube 1012. In solution reservoir 1004, the concentration of particles is maintained by a particle feed system 1014. Particle-feed system 1014 injects particles into a make-up solution 1016 through tube 1018. The quantity of particles added to make-up solution 1016 is regulated by a restrictor valve 1020 positioned in tube 1018.

Make-up solution 1016 is continuously agitated by a mechanical agitation system 1022 to ensure a uniform distribution of particles within make-up solution 1016. The volume of solution is continuously monitored in solution reservoir 1004 by a liquid-level switch 1024. Additionally, the concentration of nickel sulphamate and nickel bromide is continuously monitored by a concentration sensor 1026.

To maintain a control nickel-particle deposition rate in plating tank 1002, make-up solution 1016 is continuously recirculated to plating tank 1002 through a recirculation line 1028. A level switch 1030 in plating tank 1002 continuously monitors the volume of plating solution 1008. As plating solution 1008 is depleted in plating tank 1002, a pump 1032 is activated by level switch 1030 to provide make-up plating solution 1016 into plating tank 1002 through a nozzle 1034.

It is important to note that the component arrangement of particle plating bath 968 illustrated in FIG. 10 is merely an example of one possible arrangement of components. Those skilled in the art will appreciate that various arrangements are possible for maintaining relatively constant plating conditions within particle plating bath 968. For example, plating tank 1002 and solution reservoir 1004 can be a single unit in which plating conditions are maintained by a combination of particle make-up, concentration regulation and agitation subsystems.

Without further elaboration, it is believed that one skilled in the art can, using the preceding description, utilize the invention to its fullest extent. The following example is merely meant to illustrate the invention and not to limit the remainder of the disclosure in any way whatsoever.

### EXAMPLE I

The following procedure was used to prepare metallized contacts on a copper flex circuit, and in particular, a metallized contact to be used to electrically connect a flex circuit to an antenna coil in a smart card body.

To form the base nickel metallization, testing samples were obtained having patterned copper traces and contact lands overlying a flex circuit substrate. The test samples also included a layer of photoresist overlying the copper traces and exposing the contact lands. For purposes of experimentation, flex circuit test substrates were obtained from Multitape GmbH, Salzkotten, Germany.

The metallization of the contact lands was produced by electroplating nickel to an approximate 70-micron height over the base copper pad in a first nickel plating bath. The bath contained a nickel plating solution of nickel sulphamate (“Electropure 24” from Atotech, USA (State College, Pennsylvania)) and nickel bromide in amounts of about 80 g/l nickel and was buffered with boric acid to a pH of 2.5-4.0. The solution also included the wetting agent sodium lauryl sulfate. The bath was maintained at a temperature of about 130° F. with constant stirring.

An electrical connection was made to the test samples and they were submerged in the first plating bath to plate a base of nickel on the contact lands. The samples were submerged in the plating bath for a period of time sufficient to plate about 70 microns of nickel onto the contact lands. The nickel base height on the plated test samples was determined using a Starrett T230P inch micrometer and a surface profilometer, Surfcom 130A, from Tokyo Seimitsu Co., LTD, Tokyo, Japan.

After the nickel base was plated to the target height, the test samples were submerged in a second nickel bath containing a nickel plating solution similar to that contained in the first nickel plating bath, and further containing 20-micron nickel-coated diamond particles at a concentration of about 1 g/l. The test samples were positioned at a 45-degree angle with respect to a major plane of the mesh anode, and the solution was agitated for about 1 minute at a current density of about 100 A/ft². After forming the nickel particle layer, the test samples were returned to the first bath and plated with nickel for 3 minutes form a particle anchor layer overlying the particle layer.

### EXAMPLE II

The test samples described in Example I were plated for about 2 minutes in the first nickel plating bath. A second nickel plating bath was prepared as using the nickel plating solution described in Example I, but instead of nickel-plated diamond particles, commercial grade silicon carbide particles from Fujimi Industries were added to a concentration of about 1 g/l. The silicon carbide particles had a size of about 14-microns. The samples were submerged in the second plating bath for about 2 minutes. The plating process was carried out at a current density of about 100 A/ft². Also, the agitation in the bath was turned off immediately before the samples were submerged in the bath. After plating the silicon carbide layer, the samples were returned to the first plating bath for 6 minutes to form an adhesion layer overlying the particle layer.

### EXAMPLE III

The test samples described in Example I were plated for about 12 minutes in the first nickel plating bath. A second nickel plating bath was prepared using the nickel plating solution described in Example I, but instead of nickel-plated diamond particles, uncoated, 14-micron diamond particles were added to the bath to a concentration of about 1 g/l. The agitation in the bath was turned off, and the test samples were submerged in the bath for a period of time sufficient to form a diamond layer having a thickness of about 25 to about 35 microns. The plating process was carried out at a current density of about 100 A/ft². After plating in the particle bath, the samples were returned to the first plating bath for 7 minutes to form an adhesion layer overlying the diamond particle layer.

### EXAMPLE IV

The viability of the present method for component attachment has been demonstrated in dual interface smart cards. The position of the antenna coil within the card body determined the necessary contact height. In the cards used in the test, the coil was embedded in the card body 100 μm below the shelf formed in the cavity that receives the module. Because it is not practical to build up the 100 μm space with hard particles, a base of nickel was first deposited and then over coated with the particles. The total height was approximately 100 μm. The particles were as in Example 1 i.e. 20 μm nickel coated diamond.

The particles and metal were co-deposited in an electrolytic process. A photoresist mask was used to define the contact areas. Particle distribution within the contact area was controlled by agitation of the plating solution and substrate angle. The metal deposit was controlled by the usual plating conditions such as current density and anode placement. A protective flash of gold was applied over the deposition of the particles

The modules with the coated contacts were assembled in card bodies using a Model 385 Fully Automatic Smart Card Assembly System available from Meinen, Ziegel & Co. GmbH, Hohenkirchen, Germany using cyanoacrylate (i.e., No. 8400 from Sichel) or hot melt adhesives (i.e., TESA 8410, identified previously.) After assembly, wires were manually soldered onto the face of the contact plate to make external connection to the module/coil connection.

The performance of the contacts was evaluated by measuring the DC electrical resistance of the contacts. The resistance of both nonconductive adhesives did not change with time. Thus, smart cards and labels prepared in the manner of this invention can be tested immediately thereby improving manufacturing quality assurance while minimizing the impact on plant throughput and the potential for yield losses.

The reliability of the contact under ISO smart card flex tests was performed using ______ The test was performed in accordance with ISO standard No. 10373. The tests were not performed under contact or RF reader mode. Instead, contacts were attached to each card and the presence or absence of current was tested continuously. The ISO standard calls for satisfactory interconnect after 1000 flexes

The DC resistance of the electrical connection was monitored continuously during the flexing. Results are tabulated in Table I for cyanoacrylate adhesive and in Table II for the hot melt adhesive. An arbitrary resistance threshold of 1.0 ohm was used to discriminate between pass (“P”) and fail (“F”). “T” indicates intermittent or temporary failure.

TABLE I
Flex Reliability for CA Adhesive
Number of Flexes

| Card# | 1000 | 2000 | 3000 | 4000 | 5000 |
|---|---|---|---|---|---|
| 1 | P | P | P | P | P |
| 2 | F | F | F | F | F |
| 3 | P | P | P | P | F |
| 4 | P | T | P | P | P |
| 5 | F | F | F | F | F |
| 6 | P | F | F | F | F |

TABLE II
Flex Reliability for Hot Melt Adhesive
Number of Flexes

| Card# | 1000 | 2000 | 3000 | 4000 | 5000 |
|---|---|---|---|---|---|
| 1 | P | P | P | P | P |
| 2 | P | P | P | P | T |
| 3 | P | P | P | P | P |
| 4 | T | T | T | T | T |
| 5 | P | P | T | P | T |

Two cards assembled with cyanoacrylate (i.e., cards No. 2 and 4 in Table 1) broke during the first bending cycle apparently due to a misplacement of the module in the card during assembly. Nevertheless, the foregoing tests demonstrate that:

1. The process of the present invention can be successfully used to form physical and electrical attachments of chip to module and chip to antenna coil in dual interface mart cards.

2. Smart card components attached in accordance with the present invention meet ISO standards which require acceptable performance after 1000 flexes. (Three cards assembled with cyanoacrylate survived 4000 or more ISO flexes.)

3. The antenna/chip connection can be tested immediately after embedding the module in the card body, thus relieving a critical and expensive bottleneck associated with the production testing of cards manufactured with conductive adhesives.

4. Smart cards produced using the process of the present invention can “self-heal” during flex induced failures. It is believed that the contact can be opened during pending but upon relaxation, the contact between module and antenna coil is repaired.

5. Cards assembled with hot melt adhesive perform better during flexing. It is believed that this result can be credited to the greater flexibility of the hot melt adhesive after curing.

I claim:

1. A method for joining a first metal surface to a second metal surface, said method comprising the steps of:
a) applying a plurality of hard particles to at least a portion of one of the first and second metal surfaces, wherein the plurality of hard particles include a substance that is harder than either metal surface;
b) disposing a non-conductive adhesive on one or both of the metal surfaces;
c) aligning the metal surfaces to form an interface;
d) applying compressive force to the first and second metal surfaces in a direction generally normal to said interface, such that at least a piercing portion of the plurality of hard particles penetrate through the adhesive and pierce the second metal surface; and
e) at least partially releasing the compressive force, the first and second surfaces thereafter being secured together by said adhesive, wherein the piercing portion of the plurality of hard particles remain in piercing relationship with at least a portion of the second metal surface.

2. A method as described in claim 1, wherein the joining of the first and second metal surfaces results in an electrical coupling between the first and second metal surfaces.

3. A method as described in claim 1, wherein the joint results in thermal coupling between the first and second metal surfaces.

4. A method as described in claim 1, wherein the non-conductive adhesive is applied to the second metal surface.

5. A method as described in claim 1, wherein the non-conductive adhesive is applied to the first metal surface.

6. A method as described in claim 1, wherein the non-conductive adhesive comprises a film that is disposed on at least one of the two surfaces at the time of assembly.

7. A method as described in claim 1, wherein the non-conductive adhesive comprises a permanently hardenable adhesive that is hardened before the compressive force is removed.

8. A method as described in claim 1, wherein the non-conductive adhesive comprises a pressure-sensitive adhesive.

9. A method as described in claim 1, wherein the non-conductive adhesive comprises a hot-melt adhesive.

10. A method as described in claim 1 wherein a permanent adhesive bond is formed.

11. A method as described in claim 1 wherein a temporary adhesive bond is formed.

12. A method as described in claim 1, wherein the hard particles are affixed to the first surface by plating a thin metal layer over them on the first metal surface.

13. A method as described in claim 1, wherein the hard particles comprise a hard core surrounded by a softer metal.

14. A method as described in claim 1, wherein the hard particles comprise a metal.

15. A method as described in claim 1, wherein the hard particles are selected from the group consisting of: , copper, aluminum, nickel, tin, bismuth, silver, gold, platinum, paladium lithium, beryllium, boron, sodium, magnesium, potassium, calcium, gallium, germanium, rubidium, strontium, indium, antimony, cesium, barium, and intermetallics and alloys of these metals.

16. A method as described in claim 1, wherein the hard particles comprise a non-metallic material.

17. A method as described in claim 1, wherein at least one of the metal surfaces comprises an electrical interconnection pad of a printed circuit board.

18. A method as described in claim 17, wherein the printed circuit board comprises a smart card or smart label.

19. A method as described in claim 1, wherein at least one of the metal surfaces comprises the electrical interconnection pad or lead of an electrical component.

20. A method as described in claim 1-9, wherein the electrical component comprises a semiconductor chip.

21. An electrical component assembly comprising:
a) a substrate having a plurality of electrical contact sites on a surface thereof; and
b) a plurality of hard particles positioned on the substrate, such that each of the electrical contact sites has at least one hard particle associated therewith, the hard particles being affixed to the electrical contact sites.

22. An electrical component assembly as described in claim 21, wherein the plurality of hard particles is affixed to the electrical contact sites by a layer of plated nickel.

23. An electrical component assembly as described in claim 21 further comprising an non-conductive adhesive material applied to at least selected portions of the surface of the substrate and the plurality of hard particles.

24. An electrical component assembly as described in claim 23, wherein the non-conductive adhesive covers substantially all of the substrate.

25. An electrical component assembly as described in claim 23, wherein the non-conductive adhesive covers selected portions of the substrate.

26. An electrical component assembly as described in claim 23, wherein the plurality of hard particles is affixed to the electrical contact sites by plating a thin metal layer over the plurality of hard particles on the electrical contact sites.

27. An electrical component assembly as described in claim 21, wherein the substrate comprises a semiconductor chip.

28. An electrical component assembly as described in claim 21, wherein the hard particles are selected from the group consisting of: diamond, nickel-plated diamond, garnet and silicon carbide.

29. A method for making an electrical component assembly comprising the steps of:
a) providing a substrate having a plurality of electrical contact sites on a surface thereof;
b) positioning a plurality of hard particles on the substrate, such that each of the electrical contact sites has at least one hard particle associated therewith; and
c) affixing each hard particle to its associated contact site.

30. A method as described in claim 29, further comprising the step of applying an non-conductive adhesive material to at least selected portions of the surface of the substrate and the plurality of hard particles.

31. A method as described in claim 30, wherein the non-conductive adhesive covers substantially all of the substrate.

32. A method as described in claim 29, wherein the step of affixing comprises plating a thin metal layer over the plurality of hard particles on the electrical contact sites.

33. A method as described in claim 29, wherein the substrate comprises a semiconductor chip.

34. A method as described in claim 29, wherein the substrate comprises a printed circuit board.

35. A method as described in claim 29, wherein the substrate comprises a smart card chip module.

36. A method as described in claim 30, wherein the substrate comprises a smart label.

37. A method for making an electronic component assemblies comprising:
a) providing a substrate having a plurality of electronic components thereon, each component having a plurality of electrical contact sites on a surface thereof;
b) positioning a plurality of hard particles on the substrate, such that each of the electrical contact sites has at least one hard particle associated therewith;
c) affixing each hard particle to its associated contact site; and
d) dividing the substrate into at least two electrical component assemblies.

38. A method as described in claim 37, further comprising applying a nonconducive adhesive to cover substantially all of the substrate.

39. A method as described in claim 37, further comprising applying a nonconductive adhesive to cover selected portions of the substrate.

40. A method as described in claim 37, wherein positioning a plurality of hard particles comprises affixing the hard particles to the electrical contact sites by plating a thin metal layer over the hard particles on the electrical contact sites.

41. A method as described in claim 37, wherein the substrate comprises a semiconductor wafer.

42. A method as described in claim 37, wherein the substrate comprises a flexible tape printed circuit board.

43. A method as described in claim 37, wherein the substrate comprises a smart card chip module.

44. A method as described in claim 37, wherein the substrate comprises a smart label flexible tape.

45. A method as described in claim 37, further comprising applying a non-conductive adhesive material to at least selected portions of the surface of the substrate and the hard particles, before subdividing the substrate.

46. A method as described in claim 37, further comprising applying a non-conductive adhesive material to at least selected portions of the surface of the substrate and the hard particles, after subdividing the substrate.

47. A method for attaching an electrical component to a printed circuit board comprising the steps of:
a) providing a printed circuit board having a plurality of electrical contact sites on a surface thereof,
b) providing an electrical component having a plurality of electrical contact sites on a surface thereof, each electrical contact site on the electrical component having a corresponding electrical contact site on the surface of the printed circuit board, the electrical component further comprising a plurality of hard particles positioned on the electrical component, such that each of the electrical contact sites located on the surface of the electrical component has at least one hard particle associated therewith, the hard particles comprising a substance that is harder than the electrical contact sites on the surface of the printed circuit board, the hard particles being affixed to the electrical contact sites;
c) disposing a non-conductive adhesive on at least one of the electrical component and the printed circuit board, such that at least selected portions of the surfaces of the printed circuit board and the electrical component and the plurality of hard particles are covered by non-conductive adhesive;
d) positioning the electrical component relative to the printed circuit board, such that at least one hard particle on each contact on the substrate is in contact with the corresponding electrical contact site on the printed circuit board;
e) applying a compressive force to the component and printed circuit board so that the hard particles on the component penetrate the non-conductive adhesive and pierce into the electrical contact sites on the printed circuit board; and
f) releasing the applied compressive force, a force thereafter being maintained on the surfaces by the non-conductive adhesive, wherein the piercing portion of the hard particles remain embedded in the electrical contact sites on the printed circuit board.

48. A printed circuit interconnection assembly comprising:
a printed circuit board substrate having a plurality of electrical contact sites on a surface thereof; and
a plurality of hard particles positioned on the substrate, such that each of the plurality of electrical contact sites has at least one hard particle associated therewith, wherein the at least one hard particle is affixed to each electrical contact site.

49. A printed circuit interconnection assembly as described in claim 48 further comprising a non-conductive adhesive material applied to at least selected portions of the surface of the substrate and to the plurality of hard particles.

50. A printed circuit interconnection assembly as described in claim 49, wherein the adhesive covers substantially all of the substrate.

51. A printed circuit interconnection assembly as described in claim 48, wherein the plurality of hard particles further comprises a plated thin metal layer that affixes the plurality of hard particles to the electrical contact sites.

52. A printed circuit interconnection assembly as described in claim 48, wherein the printed circuit board substrate comprises a flexible printed circuit board substrate.

53. A printed circuit interconnection assembly as described in claim 48, wherein the printed circuit board substrate comprises a smart card chip module.

54. A printed circuit interconnection assembly as described in claim 48, wherein the printed circuit board substrate comprises a smart label.

55. A method for attaching an electrical component to a printed circuit board comprising the steps of:
a) providing an electrical component having a plurality of electrical contact sites on a surface thereof;
b) providing a printed circuit board having a plurality of electrical contact sites on a surface thereof, each electrical contact site on the board having a corresponding electrical contact site on the surface of the electrical component, the printed circuit board further comprising a plurality of hard particles positioned on the printed circuit board, such that each of the electrical contact sites located on the surface of the board has at least one hard particle associated therewith, the hard particles comprising a substance that is harder than the electrical contact sites on the surface of the electrical component, the hard particles affixed to the electrical contact sites;
c) disposing a non-conductive adhesive on at least one of the electrical component and the printed circuit board, such that at least selected portions of the surfaces of the electrical component and the printed circuit board and the plurality of hard particles are covered by the non-conductive adhesive;
d) positioning the electrical component relative to the printed circuit board, such that at least one hard particle on each contact on the printed circuit is in contact with the corresponding electrical contact site on the electrical component;
e) applying a compressive force to the component and printed circuit board so that the hard particles on the board penetrate the non-conductive adhesive and pierce into the electrical contact sites on the component; and
f) releasing the applied compressive force, a force thereafter being maintained on the surfaces by the non-conductive adhesive, wherein the piercing portion of the hard particles remaining embedded in the electrical contact sites on the printed circuit board.

56. A method for plating hard particles onto a substrate comprising:
providing a metal plating solution including hard particles in a plating tank; positioning an anode submerged in the plating solution;
positioning the substrate in proximity to the anode;
agitating the metal plating solution; and
plating metal and hard particles onto the substrate.

57. A method as described in claim 56, further comprising:
providing a particle solution reservoir containing a make-up solution comprising additional hard particles and additional metal plating solution, wherein the particle solution reservoir is coupled to the plating tank by a drain and a recirculation conduit; and
recirculating make-up solution through the recirculation conduit to the plating tank,
whereby the step of agitating is provided by the step of recirculating the make-up solution through the plating tank.

58. A method as described in claim 56, wherein the hard particles comprise metal particles.

59. A method as described in claim 58, wherein the metal particles comprise particles selected from the group consisting of: , copper, aluminum, nickel, tin, bismuth, silver, gold, platinum, paladium lithium, beryllium, boron, sodium, magnesium, potassium, calcium, gallium, germanium, rubidium, strontium, indium, antimony, cesium, barium, and intermetallics and alloys of these metals.

60. A method as described in claim 56, wherein the hard particles comprise non-metallic particles.

61. A method as described in claim 60, wherein the non-metallic particles comprise particles selected from the group consisting of: garnet, diamond, and silicon carbide.

62. A method as described in claim 56, wherein the hard particles comprise particles having a hard core surrounded by a softer metal material.

63. A method as described in claim 62, wherein the hard particles comprise nickel-coated diamond particles.

64. A method as described in claim 56, wherein the metal plating solution comprises a nickel plating solution.

65. A method as described in claim 56, wherein the anode comprises a mesh structure.

66. A method as described in claim 56, wherein the anode comprises platinum coated titanium.

67. A method for plating hard particles onto a flexible tape substrate comprising:
providing a particle plating solution including hard particles in a plating tank;
positioning an anode in the plating solution;
agitating the particle plating solution;
drawing the flexible circuit tape through the particle plating solution in proximity to the anode; and
plating a layer of hard particles onto the flexible tape substrate.

68. A method as described in claim 67, further comprising:
providing a particle solution reservoir containing a make-up solution comprising additional particle plating solution, wherein the particle solution reservoir is coupled to the plating tank by a drain and a recirculation conduit; and
recirculating make-up solution through the recirculation conduit to the plating tank,
whereby the step of agitating is provided by the step of recirculating the make-up solution through the plating tank.

69. A method as described in claim 67 further comprising:
drawing the flexible tape substrate through a second plating bath; and
plating a layer of metal onto the layer of particles.

70. A method as described in claim 69, wherein the second plating bath plates a layer comprised of nickel onto the layer of particles.

71. A method as described in claim 69 further comprising:
drawing the flexible tape substrate through a third plating bath; and
plating a second layer of metal onto the layer of particles.

72. A method as described in claim 71, wherein the third plating bath plates a layer comprised of gold onto the layer of particles.

73. A method as described in claim 67 further comprising drawing the flexible tape substrate through a cleaning bath before drawing the flexible tape substrate through the particle plating bath.

74. A method as described in claim 67 further comprising drawing the flexible circuit tape through an etching bath before drawing the flexible tape substrate through the particle plating bath.

75. A method as described in claim 67 further comprising:
drawing the flexible tape substrate through a preliminary plating bath before drawing the flexible tape substrate through the particle plating bath; and
plating a preliminary layer of metal onto the flexible tape substrate.

76. A method as described in claim 75, wherein the preliminary plating bath plates a layer comprised of nickel onto the flexible tape substrate.

77. A method as described in claim 67, wherein the flexible tape substrate is at least partially covered by a layer of photoresist, the method further comprising drawing the flexible tape substrate through a photoresist removal bath after drawing the flexible tape substrate through the particle plating bath.

78. A method as described in claim 77 further comprising drawing the flexible tape substrate through a second cleaning bath after drawing the flexible tape substrate through the photoresist removal bath.

79. A method as described in claim 78 further comprising drawing the flexible tape substrate through an etching bath after drawing the flexible tape substrate through the second cleaning bath.

80. A method as described in claim 67, wherein the flexible tape substrate comprises a flexible circuit tape.

81. A method as described in claim 67, wherein the flexible tape substrate comprises a flexible tape with small rigid components affixed to and spaced apart along a surface of the flexible tape.

82. A method as described in claim 67, wherein the anode comprises a mesh structure.

83. A method as described in claim 67, wherein the anode comprises platinum coated titanium.

84. A method as described in claim 67, wherein the particle plating solution comprises a metal plating solution including hard particles.

85. A method as described in claim 84, wherein the metal plating solution comprises a nickel plating solution.

86. A method as described in claim 67, wherein the hard particles comprise metal particles.

87. A method as described in claim 86, wherein the metal particles are selected from the group consisting of: , copper, aluminum, nickel, tin, bismuth, silver, gold, platinum, paladium lithium, beryllium, boron, sodium, magnesium, potassium, calcium, gallium, germanium, rubidium, strontium, indium, antimony, cesium, barium, and intermetallics and alloys of these metals.

88. A method as described in claim 67, wherein the hard particles comprise non-metallic particles.

89. A method as described in claim 88, wherein the non-metallic particles comprise particles selected from the group consisting of garnet, diamond and silicon carbide.

90. A method as described in claim 67, wherein the hard particles comprise particles having a hard core surrounded by a softer metal material.

91. A method as described in claim 90, wherein the hard particles comprise nickel-coated diamond.

92. A method as described in claim 90, wherein the step of plating further comprises the step of charging the flexible tape substrate as a cathode.
